(19) United States
(12) Patent Application Publication
(10) Pub. No.: US 2024/0352580 A1
(43) Pub. Date: Oct. 24, 2024

(54) SIDE PUMPING CHAMBER AND DOWNSTREAM RESIDUE MANAGEMENT HARDWARE

(71) Applicant: Applied Materials, Inc., Santa Clara, CA (US)

(72) Inventors: Zaoyuan Ge, San Jose, CA (US); Prasath Poomani, Dharmapuri (IN); Yin Xiong, Santa Clara, CA (US); Ajit Laxman Kulkarni, Vadodara (IN); Sungwon Ha, Palo Alto, CA (US); Amit Bansal, Milpitas, CA (US); Abdul Aziz Khaja, San Jose, CA (US); Sarah Michelle Bobek, Santa Clara, CA (US); Badri N. Ramamurthi, Los Gatos, CA (US)

(73) Assignee: Applied Materials, Inc., Santa Clara, CA (US)

(21) Appl. No.: 18/303,391

(22) Filed: Apr. 19, 2023

(51) Int. Cl. C23C 16/44; C23C 16/52

(52) U.S. Cl. CPC C23C 16/4408; C23C 16/4412; C23C 16/52

(57) ABSTRACT

Exemplary semiconductor processing chambers may include a chamber body having sidewalls and a base. The chambers may include a pumping liner seated atop the chamber body. The pumping liner may at least partially define an annular pumping plenum and at least one exhaust aperture that fluidly couples the pumping plenum with an interior of the chamber body. The chambers may include a purge ring seated below the pumping liner. The purge ring may define an annular channel that extends about a body of the purge ring. The purge ring may define a gas inlet that is fluidly coupled with the annular channel. The purge ring may define purge ports that are disposed at different radial positions about the purge ring, each of the purge ports being aligned and in fluid communication with the pumping plenum. The chambers may include a purge gas source coupled with the gas inlet.

### TECHNICAL FIELD

The present technology relates to components and apparatuses for semiconductor manufacturing. More specifically, the present technology relates to processing chamber components and other semiconductor processing equipment.

### BACKGROUND

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process.

Thus, there is a need for improved systems and methods that can be used to produce high quality devices and structures. These and other needs are addressed by the present technology.

### SUMMARY

Exemplary semiconductor processing chambers may include a chamber body having sidewalls and a base. The chambers may include a pumping liner seated atop the chamber body. The pumping liner may at least partially define an annular pumping plenum and at least one exhaust aperture that fluidly couples the pumping plenum with an interior of the chamber body. The chambers may include a purge ring seated below the pumping liner. The purge ring may define an annular channel that extends about a body of the purge ring. The purge ring may define a gas inlet that is fluidly coupled with the annular channel. The purge ring may define a plurality of purge ports that are disposed at different radial positions about the purge ring, each of the plurality of purge ports being aligned and in fluid communication with the pumping plenum. The chambers may include a purge gas source coupled with the gas inlet.

In some embodiments, the chambers may include an exhaust assembly fluidly coupled with the pumping plenum. An outlet of each of the plurality of purge ports may point down. The chambers may include a faceplate seated atop the purge ring. The chambers may include a thermal isolator disposed between the faceplate and the purge ring. The purge ring may include aluminum. An outer surface of the purge ring may include a lateral protrusion. The gas inlet may be disposed on the lateral protrusion. The chambers may include a weldment that extends between and couples the purge gas source with the gas inlet.

Some embodiments of the present technology may encompass purge rings. The purge rings may include a ring body having a first surface and a second surface opposite the first surface. The ring body may define an open interior. The purge ring may define an annular channel that extends about the ring body. The purge ring may define a gas inlet that is fluidly coupled with the annular channel. The purge ring may define a plurality of purge ports that are disposed at different radial positions about the purge ring. The plurality of purge ports may be fluidly coupled with the annular channel.

In some embodiments, the plurality of purge ports may provide substantially uniform flow conductance about a periphery of the open interior. A cross-sectional area of the annular channel may be equal to or greater than a total cross-sectional area of the plurality of purge ports. The gas inlet may be disposed within a lateral protrusion that extends radially outward from an outer surface of the ring body. The plurality of purge ports may be disposed at irregular intervals about periphery of the open interior. At least some of the plurality of purge ports may have different cross-sectional areas. An outlet of each of the plurality of purge ports may be angled relative to a plane extending through an entirety of the annular channel. Each of the plurality of purge ports may be substantially orthogonal to the plane. The purge ring may define a plurality of purge channels. Each purge channel of the plurality of purge channels may extend between and fluidly couples the annular channel and a respective one of the plurality of purge ports.

Some embodiments of the present technology may encompass methods of processing a substrate. The methods may include flowing a precursor into a processing chamber. The methods may include generating a plasma of the precursor within a processing region of the processing chamber. The methods may include depositing a material on a substrate disposed within the processing region. The methods may include exhausting the precursor from the processing chamber via a plenum of a pumping liner disposed atop a chamber body of the processing chamber. The methods may include flowing a purge gas into the plenum of the pumping liner via a plurality of purge ports formed in a purge ring positioned below the pumping liner.

In some embodiments, the methods may include venting the precursor and the purge gas from the processing chamber and the pumping liner via a foreline, a throttle valve, and a pump. The purge gas may include O2.

Such technology may provide numerous benefits over conventional systems and techniques. For example, embodiments of the present technology may utilize a purge ring positioned below a pumping liner to direct purge gas into an exhaust assembly, including one or more forelines, throttle valves, and/or pumps to prevent and/or remove residue from components of the exhaust assembly of the processing system. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIGS. 3A-3C show a schematic cross-sectional views of an exemplary purge ring according to some embodiments of the present technology.

FIG. 4 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

During and/or after processing operations, precursors and/or other process gases and/or plasma radicals thereof may be exhausted from a processing region via an exhaust assembly, which may include, for example, a pumping liner, one or more forelines, one or more throttle valves, and/or one or pumps. Residue caused by radicals from such process gases may collect on components of the exhaust assembly and/or other nearby chamber components. These residues necessitate more often and more intensive cleaning of the chamber equipment, which may lead to downtime and service costs. Additionally, the accumulation of residues may lead to shorter service lives of the various components. Additionally, residue accumulation within the throttle valve may reduce the cross-sectional area of the flow path of the throttle valve, which effectively changes the flow conductance through the throttle valve and causes throttle valve drift. For example, over time the accumulation of residue requires the throttle valve to open to a greater degree (drift) to maintain a desired conductance due to the reduction in cross-sectional area of the flow path. This throttle drift changes the cross-sectional area of the flow path associated with each angle of the throttle valve and, over time, requires the throttle valve to be opened to greater angles to account for the decrease in conductance and change in pressure of gases flowing through the throttle valve. At larger angles, the throttle valve becomes more difficult to control to deliver precise conductance and fluid pressures.

The present technology overcomes these challenges by utilizing a purge ring that is interfaced with the exhaust assembly, such as being fluidly coupled with and/or between the pumping liner and downstream components of the exhaust assembly. The purge ring may define a number of purge ports that may direct purge gas at a position near the faceplate and direct the purge gas to a downstream region of the exhaust assembly. The purge gas may be flowed during processing operations, which may reduce or prevent the radicals from process gases from forming residue deposits within the lower region. Additionally, the purge gas may remove any residue that is present. This reduction of residue may reduce the frequency and/or intensity of cleaning operations, and may increase the service life of chamber components. Additionally, embodiments may reduce throttle valve drift and improve flow conductance through the foreline. Accordingly, the present technology may reduce the occurrence of residue deposits within the chamber.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

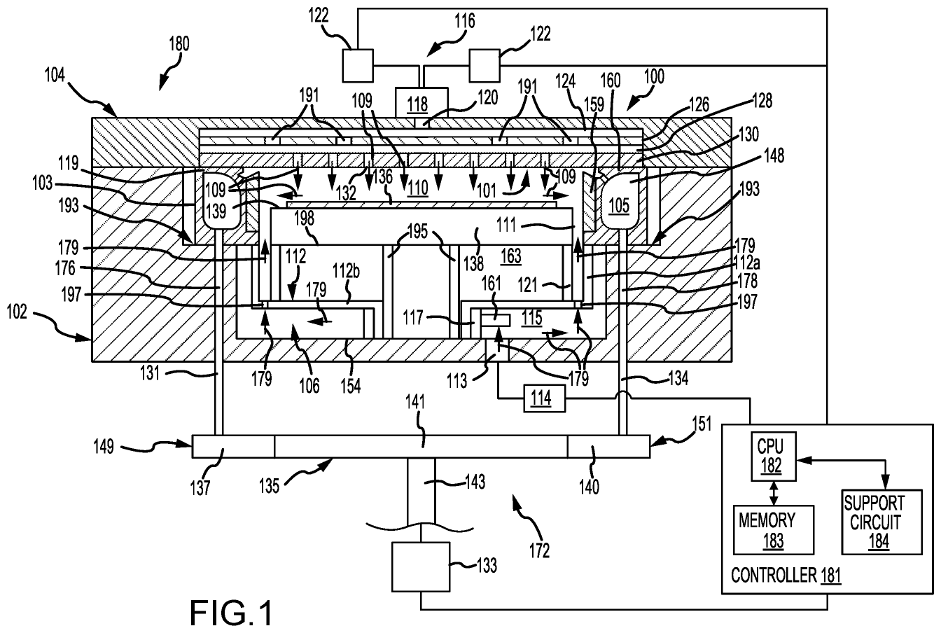

FIG. 1 shows a schematic cross-sectional view of an exemplary substrate processing chamber 100, according to one implementation. The substrate processing chamber 100 may be, for example, a chemical vapor deposition (CVD) chamber or a plasma enhanced CVD chamber. The present disclosure contemplates that other chambers may be used, such as an atomic layer deposition (ALD) chamber or a physical vapor deposition (PVD) chamber. The substrate processing chamber 100 may have a chamber body 102 and a chamber lid 104 disposed on the chamber body 102. The chamber body 102 may define an internal volume 106 between one or more sidewalls and a base of the chamber body 102 and the chamber lid 104. The chamber body 102 may be made of a single body, or two or more bodies.

The substrate processing chamber 100 may include a gas distribution assembly 116 coupled to or disposed in the chamber lid 104 to deliver a flow of one or more process gases 109 into a processing region 110 through a showerhead 101. The one or more process gases may include one or more of Ar and/or C3H6, among other gases. In one example, the one or more process gases may include one or more reactive gases. The showerhead 101 may include a backing plate 126 and a faceplate 130. The gas distribution assembly 116 may include a gas manifold 118 coupled to a gas inlet passage 120 formed in the chamber lid 104. The gas manifold 118 may receive a flow of one or more processing gases from one or more gas sources 122. While two gas sources 122 are shown, any number of gas sources may be provided in various embodiments. The flow of processing gases received from the one or more gas sources 122 may distribute across a gas box 124, flow through a plurality of openings 191 of the backing plate 126, and further distribute across a plenum 128 defined by the backing plate 126 and the faceplate 130. The flow of processing gases 109 may then flow into a processing region 110 of the internal volume 106 through one or more gas openings 132 formed in a lower surface 119 of the faceplate 130 of the showerhead 101.

A substrate support 138 may be disposed within internal volume 106 defined by the chamber body 102. The substrate supports 138 may be pedestals as illustrated, although a number of other configurations may also be used. The substrate support 138 may support a substrate 136 within the substrate processing chamber 100. The substrate support 138 may support the substrate 136 on a support surface 139 of the substrate support 138. The substrate support 138 may include a heater and/or an electrode disposed therein. The electrode may receive direct current (DC) voltage, radio frequency (RF) energy, and/or alternating current (AC) energy to facilitate processing. The lower surface 119 of the faceplate 130 of the showerhead 101 may face the support surface 139 of the substrate support 138. The support surface 139 may face the lower surface 119 of the faceplate 130 of the showerhead 101. The substrate support 138 may be made of a single body, or two or more bodies.

The substrate support 138 may be movably disposed in the internal volume 106 by a lift system 195. Movement of the substrate support 138 may facilitate transfer of the substrate 136 to and from the internal volume 106 through a slit valve formed through the chamber body 102. The substrate support 138 may also be moved to different processing positions for processing of the substrate 136.

During substrate processing, as process gases (such as the process gases 109) flow into the processing region 110, a heater may heat the substrate support 138 and the support surface 139. Also during substrate processing, the electrode in the substrate support 138 may propagate radio frequency (RF) energy, alternating current (AC), or direct current (DC) voltage to facilitate plasma generation in the processing region 110 and/or to facilitate chucking of the substrate 136 to the substrate support 138. The heat, gases, and energy from the electrode in the substrate support 138 may facilitate deposition of a film onto the substrate 136 during substrate processing. The faceplate 130, which may be grounded via coupling to the chamber body 102, and the electrode of the substrate support 138, may facilitate formation of a capacitive plasma coupling. When power is supplied to the electrode in the substrate support 138, an electric field may be generated between the faceplate 130 and substrate support 138 such that atoms of gases present in the processing region 110 between the substrate support 138 and the faceplate 130 are ionized and release electrons. The ionized atoms accelerate to the substrate support 138 to facilitate film formation on the substrate 136.

A pumping device 103 may be disposed in the substrate processing chamber 100. The pumping device 103 may facilitate removal of gases from the internal volume 106 and processing region 110. The gases exhausted by the pumping device 103 may include one or more of a process gas and a process residue. The process residue may result from the process of depositing a film onto the substrate 136.

The pumping device 103 may include a pumping liner 160 disposed on the chamber body 102. For example, the pumping liner 160 may be seated on a stepped surface 193 of the chamber body 102 and a liner 159 may be disposed between the substrate support 138 and the pumping liner 160. The stepped surface 193 may be stepped upwards from a bottom surface 154 of the chamber body 102. The pumping liner 160 may be made of a single body, or two or more bodies. The pumping liner 160 may be made from material including one or more of aluminum, aluminum oxide, and/or aluminum nitride. The liner 159 may be made from an electrically isolating material, such as a ceramic material. In one example, the liner 159 may be made of one or more of quartz, a ceramic material including aluminum such as aluminum oxide and/or aluminum nitride, or any other suitable material. The pumping liner 160 may be disposed around the substrate support 138 and may encircle the substrate support 138. A portion of a purge gas flow path 111 may be defined by an inner surface of the liner 159 and a lateral exterior surface of the substrate support 138. The substrate processing chamber 100 may include a purge gas inlet 113 disposed at a bottom of the chamber body 102. The purge gas inlet 113 may be an opening formed in a bottom surface of the chamber body 102. The purge gas inlet 113 may be fluidly coupled with a purge gas source 114 that supplies one or more purge gases 179 to the purge gas inlet 113. A bowl 112 may be disposed in the internal volume 106. The bowl 112 may define a purge gas volume 115. One or more bellows 117 may be disposed in the purge gas volume 115. One or more purge gas baffles 161 may be disposed in the purge gas volume 115. One or more bellows 121 may be disposed above a horizontal portion 112b of the bowl 112 and below a bottom surface 198 of the substrate support 138. The one or more bellows 121 may separate a dead volume 163 from a portion of the purge gas flow path 111 that is between the one or more bellows 121 and a vertical portion 112a of the bowl 112.

During substrate processing operations, and while processing gases 109 flow into the processing region 110 from the showerhead 101, the purge gas inlet 113 may flow the one or more purge gases 179 into the purge gas volume 115. The horizontal portion 112b of the bowl 112 may include one or more purge gas openings 197 that flow the purge gases 179 from the purge gas volume 115 and into the purge gas flow path 111. The one or more purge gas openings 197 may be disposed radially outwardly of the one or more bellows 121. While the processing gases 109 flow toward the substrate 136 to deposit films on the substrate 136, the purge gases 179 may flow upwards in the purge gas flow path 111 to prevent the processing gases 109 from diffusing downwards into the purge gas flow path 111. The processing gases 109 and the purge gases 179 may meet and/or mix at a diffusion position that is proximate the support surface 139. The processing gases 109 and the purge gases 179 may mix to form a gas mixture 148 that is exhausted by the pumping device 103. The pumping device 103 may include the pumping liner 160 and the liner 159.

The one or more purge gases 179 may include one or more inert gases, such as one or more of Ar and/or N2. The one or more process gases 109 may flow into the processing region 110 from the showerhead 101 at a first flow rate. In one example, the first flow rate may be a volumetric flow rate having units of standard cubic centimeters per minute (SCCM). The one or more purge gases 179 may flow into the purge gas volume 115 from the purge gas inlet 113 at a second flow rate. In one example, the second flow rate may be a volumetric flow rate having units of SCCM. The second flow rate may be a ratio R1 relative to the first flow rate. For example, the ratio R1 may be within a range of 0.25 to 0.75 of the first flow rate, within a range of 0.25 to 0.50 of the first flow rate, or within a range of 0.48 to 0.52. In one embodiment, which can be combined with other embodiments, the ratio R1 may be about 0.25, 0.30, 0.40, or 0.5 of the first flow rate. The ranges and examples of the ratio R1 of the second flow rate relative to the first flow rate may incur benefits such as preventing at least a portion of processing gases from diffusing into the purge gas flow path 111 below the support surface 139 during substrate processing operations. Reducing or preventing such diffusion reduces or eliminates the likelihood that processing gases 109 will deposit materials onto surfaces other than the substrate 136. Reducing deposition on surfaces other than the substrate 136 reduces or eliminates delays, throughput reductions, operational costs, cleaning time, and/or substrate defects.

The substrate processing chamber 100 may be part of a substrate processing system 180 that includes a controller 181 coupled to the substrate processing chamber 100. The controller 181 may be part of a non-transitory computer readable medium.

The controller 181 may control aspects of the substrate processing chamber 100 during substrate processing. The controller 181 include a central processing unit (CPU) 182, a memory 183, and a support circuit 184 for the CPU 182. The controller 181 may facilitate control of the components of the substrate processing chamber 100. The controller 181 may be a computer that can be used in an industrial setting for controlling various chamber components and sub-processors. The memory 183 may store instructions, such as software (source code or object code), that may be executed or invoked to control the overall operations of the substrate processing chamber 100 in manners described herein. The controller 181 may manipulate respective operations of controllable components in the substrate processing chamber 100. For example, the controller 181 may control the operations of the gas sources 122 to introduce processing gases, the purge gas source 114 to introduce purge gases, and/or a vacuum pump 133 (described below) to exhaust gases to eliminate or reduce contaminant particles (such as residue) in the substrate processing chamber. As an example, the controller 181 may control the lift system 195 to raise and lower the substrate support 138, and the heater and the electrode of the substrate support 138 to supply heat and energy to facilitate processing.

The pumping liner 160 may be fluidly coupled to a foreline 172 through a first conduit 176 and a second conduit 178. The foreline 172 may include a first vertical conduit 131, a second vertical conduit 134, a horizontal conduit 135, and an exit conduit 143. The exit conduit 143, in one example, is a third vertical conduit. In one example, the first conduit 176 and the second conduit 178 may be openings formed in the chamber body 102. The first conduit 176 and/or the second conduit 178 may be tubes or other flow devices that extend between a surface of the chamber body 102, such as bottom surface 154, and the pumping liner 160. As an example, the first conduit 176 and/or the second conduit 178 may be part of the first vertical conduit 131 and the second vertical conduit 134, respectively. In such an example, the first vertical conduit 131 and the second vertical conduit 134 may extend through the chamber body 102 and be coupled to the pumping liner 160. In one embodiment, which can be combined with other embodiments, the first conduit 176 and the second conduit 178 each may be an opening formed in one or more sidewalls of the chamber body 102.

The first conduit 176 may be fluidly coupled to the pumping liner 160 and the first vertical conduit 131 of the foreline 172. The second conduit 178 may be fluidly coupled to the pumping liner 160 and the second vertical conduit 134 of the foreline 172. The first vertical conduit 131 and the second vertical conduit 134 may be fluidly coupled to the horizontal conduit 135. The horizontal conduit 135 may include a first portion 137 coupled to the first vertical conduit 131, a second portion 140 coupled to the second vertical conduit 134, and a third portion 141 coupled to the exit conduit 143. The horizontal conduit 135 may include a first end 149 adjacent to the first vertical conduit 131 and a second end 151 adjacent to the second vertical conduit 134. The horizontal conduit 135 may be made up of a single body or can be fabricated from one or more components.

The first conduit 176, second conduit 178, first vertical conduit 131, second vertical conduit 134, and horizontal conduit 135 may be configured to direct gases therethrough. The first conduit 176, second conduit 178, first vertical conduit 131 and/or second vertical conduit 134 need not be completely vertical and may be angled or may include one or more bends and/or angles. The present horizontal conduit 135 need not be completely horizontal and may be angled or may include one or more bends and/or angles.

The exit conduit 143 may be fluidly coupled to a vacuum pump 133 to control the pressure within the processing region 110 and to exhaust gases and residue from the processing region 110. The vacuum pump 133 may exhaust gases from the processing region 110 through the pumping liner 160, the first conduit 176, the second conduit 178, the first vertical conduit 131, the second vertical conduit 134, the horizontal conduit 135, and the exit conduit 143 of the foreline 172.

The pumping liner 160 may be fluidly coupled to the exit conduit 143 through the second conduit 178, second vertical conduit 134 and the horizontal conduit 135. The gas mixture 148 may flow from the annulus 105, through the exhaust port 145, and into the second conduit 178. A second exhaust port of the pumping liner 160 may be disposed between the annulus 105 and the first conduit 176. The second exhaust port may be fluidly coupled to the exit conduit 143 through the first conduit 176, first vertical conduit 131 and the horizontal conduit 135. In addition to flowing through the exhaust port 145, the gas mixture 148 may flow through the second exhaust port and into the first conduit 176.

The first vertical conduit 131 may flow the gas mixture 148 from the first conduit 176 and into the first portion 137 of the horizontal conduit 135. The second vertical conduit 134 may flow the gas mixture 148 from the second conduit 178 and into the second portion 140 of the horizontal conduit 135. The first portion 137 and the second portion of the horizontal conduit 135 may flow the gas mixture 148 from the first vertical conduit 131 and the second vertical conduit 134, respectively, and into the third portion 141 of the horizontal conduit 135. The third portion 141 of the horizontal conduit 135 may flow the gas mixture 148 from the horizontal conduit 135 and into the exit conduit 143. The exit conduit 143 may exhaust the gas mixture 148 from the exhaust port 145 and the second exhaust port that is disposed between the annulus 105 and the first conduit 176.

Although two conduits 176, 178; two vertical conduits 131, 134; and a pumping liner 160 with an exhaust port 145 and a second exhaust port are illustrated, any number of conduits, vertical conduits, and/or exhaust ports may be implemented in various embodiments. For example, the pumping liner 160 may have at least three exhaust ports that are fluidly coupled to respective conduits and vertical conduits. The third conduit may be coupled to the third vertical conduit and the third vertical conduit may be coupled to the horizontal conduit 135. The three exhaust ports may be disposed along a circumferential axis of the pumping liner 160 approximately equidistant from each other, such as 120 degrees from each other.

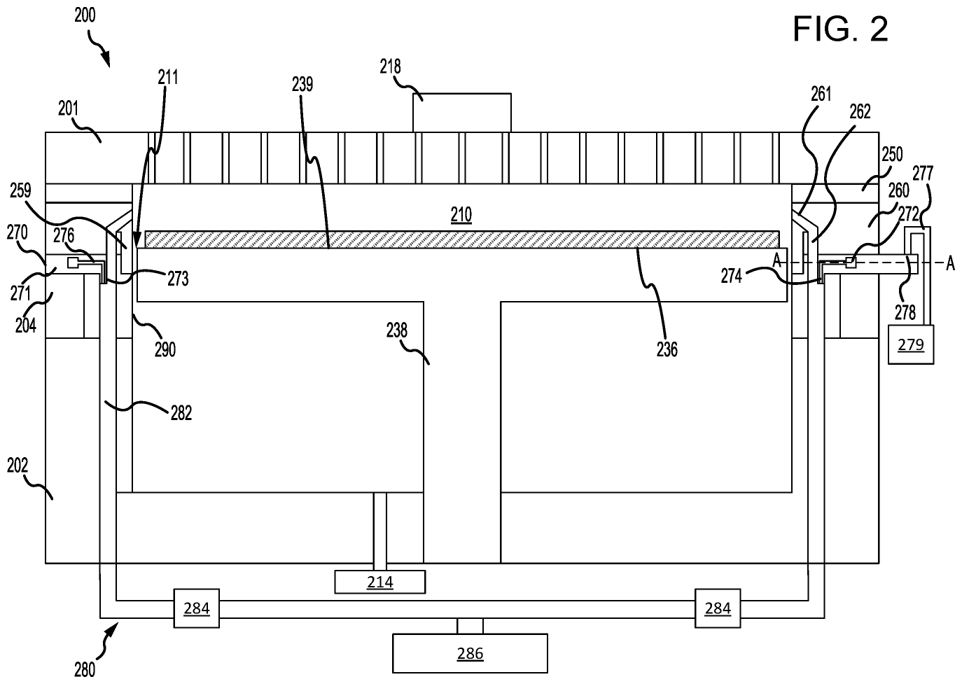

FIG. 2 shows a schematic partial cross-sectional view of an exemplary semiconductor processing chamber 200 according to some embodiments of the present technology. FIG. 2 may include one or more components discussed above with regard to FIG. 1, and may illustrate further details relating to that chamber. Chamber 200 is understood to include any feature or aspect of chamber 100 discussed previously in some embodiments. The chamber 200 may be used to perform semiconductor processing operations including deposition of hardmask materials as previously described, as well as other deposition, removal, and cleaning operations. Chamber 200 may show a partial view of a processing region of a semiconductor processing system, and may not include all of the components, and which are understood to be incorporated in some embodiments of chamber 200.

As noted, FIG. 2 may illustrate a portion of a processing chamber 200. The chamber 200 may include a number of lid stack components, which may facilitate delivery or distribution of materials through the processing chamber 200 into a processing region 210. A chamber lid plate 204 may extend across one or more plates of the lid stack and may provide structural support for various components, such as an output manifold 218. Chamber 200 may include a chamber body 202, a gas box, a backing plate, and/or a faceplate/showerhead 201.

Chamber 200 may include a substrate support 238, which may include a support surface 239 on which a substrate 236 may be supported. The substrate support 238 may include a heater and/or an electrode disposed therein. The electrode may receive direct current (DC) voltage, radio frequency (RF) energy, and/or alternating current (AC) energy to facilitate processing. The substrate support 238 may be vertically translatable along a central axis of the substrate support 238 between a transfer position, and a process position as illustrated. For example, a lift system may be used to raise and lower the substrate support 238 between the transfer position and one or more process positions. In the transfer position, substrates 236 may be transferred to and from the substrate support 238 via a slit valve formed through the chamber body 202.

A pumping liner 260 may be disposed about an exterior surface of the substrate support 238. The pumping liner 260 may be seated atop the chamber body 202. For example, in some embodiments, the pumping liner 260 may be seated directly atop the chamber body 202, while in other embodiments one or more components may be disposed between the pumping liner 260 and the chamber body 202. For example, an isolator 290 and/or lid plate 204 may be positioned between the chamber body 202 and the pumping liner 260. The pumping liner 260 may define an annular pumping plenum 262 in some embodiments. The pumping plenum 262 may be a continuous annular volume and/or may be formed a of plurality of individual volumes that are arranged in an annular shape about a circumference of the pumping liner 260. The pumping liner 260 may define a plurality of exhaust apertures 261 that fluidly couple the pumping plenum 262 with an interior of the chamber body 202 (e.g., the processing region 210). In some embodiments, a thermal isolator 250 may be disposed between the faceplate 201 and the pumping liner 260.

A liner 259 may be disposed between the substrate support 238 and the pumping liner 260. For example, an outer surface of the liner 259 may be positioned against an inner surface of the pumping liner 260, with an inner surface of the liner 259 being spaced apart from the exterior surface/peripheral edge of the substrate support 238 to enable the substrate support 238 to translate relative to the liner 259. The exterior surface/peripheral edge of the substrate support 238 and the inner surface of the liner 259 may define a gap that operates as a purge lumen 211. For example, a purge gas source 214 may deliver a purge gas through a lumen formed in a bottom and/or sidewall of the chamber body 202, with the purge gas helping to prevent deposition gases and/or plasma radicals from flowing below the substrate support 238 during processing operations. The liner 259 may be made from an electrically isolating material, such as a ceramic material. In one example, the liner 259 may be made of quartz, a ceramic material including aluminum such as aluminum oxide and/or aluminum nitride, and/or any other suitable material. The top inner edge and/or the top outer edge of the liner 259 may be rounded and/or chamfered, which may help reduce or eliminate surface singularities that may create flow separation and/or otherwise impact flow uniformity through the purge lumen 211. A size of the purge lumen 211 may be constant or substantially constant as shown here. In some embodiments, a design of the liner 259 may be adjusted to create a purge gas flow path with a variable cross-section at one or more locations.

The chamber 200 may include an exhaust assembly 280 that is coupled with the pumping plenum 262 of the pumping liner 260. The exhaust assembly 280 may include one or more forelines 282 and/or other exhaust lines that may fluidly couple the pumping plenum 262 with one or more pumps 286, which may be used to create a negative pressure to draw process, purge, and/or cleaning gases (and/or radicals thereof) out of the processing region 210 via the pumping liner 260. The forelines 282 may extend through the isolator 290, chamber body 202, and/or other components positioned between the pumping liner 260 and the pump 286. In some embodiments, the forelines 282 may include a number of distinct cylindrical (or other cross-sectional shaped) exhaust lumens, while in other embodiments the forelines 282 may include one or more annular voids or other fluid paths that extend about all or part of the circumference of the chamber 200. For example, as illustrated each of the isolator 290 and chamber body 202 (or other components below the pumping liner 260) may define an annular void that operates as all or a portion of a foreline 282. The annular void may extend all the way down the chamber body 202 and/or may extend partially through a depth of the chamber body 202 and then transition to one or more smaller foreline portions, such as cylindrical forelines 282. One or more throttle valves 284 may be coupled with the forelines 282 upstream of the pump 286. The throttle valves 284 may control a flow rate and/or pressure within the forelines to help control the flow of gases through the exhaust assembly 280.

Chamber 200 may include a purge ring 270, which may be seated below the pumping liner 260 and faceplate 201 in some embodiments. For example, the purge ring 270 may be seated top the lid plate 204, isolator 290, and/or chamber body 202, with a bottom surface of the pumping liner 260 being seated atop an upper surface of the purge ring 270. The purge ring 270 may include a ring body that has a first upper surface and a second lower surface opposite the first surface. The ring body may include an outer body 271 and an inner body 273 that defines an open interior. The inner body 273 may protrude downward from the second surface of the ring body and may extend beyond the bottom surface of the outer body 271. For example, the inner body 273 may extend into the annular void of the forelines 282, with a bottom edge of the inner body 273 being disposed alongside isolator 290. The purge ring 270 may define an annular channel 272 that extends all or substantially all the way about the circumference of the ring body. The purge ring 270 may define a plurality of purge ports 274 that are disposed at different radial positions about the purge ring 270. The purge ports 274 may be fluidly coupled with the annular channel 272. For example, a radial purge channel 276 may extend between and fluidly coupled the annular channel 272 and one of the purge ports 274. In some embodiments, each purge channel 276 may include a horizontal portion that extends inward from the annular channel 272 to a position that is vertically above a purge port 274. A vertical portion may extend downward from an inner end of the horizontal portion and may couple with the purge port 274. In other embodiments, other purge channel designs, such as angled channels, may be utilized. Each of the purge ports 274 be aligned and in fluid communication with the pumping plenum 262. For example, each of the purge ports 274 may open into the annular void of the forelines 282, such as at a position just below the pumping liner 260. In some embodiments, such as illustrated here, each purge port 274 points downward (e.g., within 15 degrees of vertical, within 10 degrees of vertical, within 5 degrees of vertical, within 3 degrees of vertical, within 1 degree of vertical, or less), however other angles are possible in various embodiments. For example, the purge ports 274 may be directed inward and/or angled inward/outward and downward. In some embodiments each purge port 274 is directed at a same angle relative to a central axis of the open interior of the purge ring 270.

The purge ring 270 may define a gas inlet 278 that may be fluidly coupled with the annular channel 272, and a purge gas source 279 may be fluidly coupled with the gas inlet 278, such as via one or more weldments 277 and/or other fluid lines. This may enable a purge gas, such as, but not limited to, 02 to be flowed from the purge gas source 279 into the forelines 282 via the purge ports 274. The flow of purge gas into the exhaust assembly 280 may help to reduce the amount of residue that may be deposited on components of the exhaust assembly 280 (e.g., the forelines 282, throttle vales 284, pump 286, etc.), and may possibly help prevent and/or reduce deposition of residue on portions of chamber components proximate the purge ring 270, such as the pumping liner 260, substrate support 238, and/or faceplate 201. The reduction in residue within the throttle valves 284 may help maintain proper conductance through the throttle valves 284 and reduce the amount of throttle valve drift, which in turn may reduce the frequency of cleaning operations.

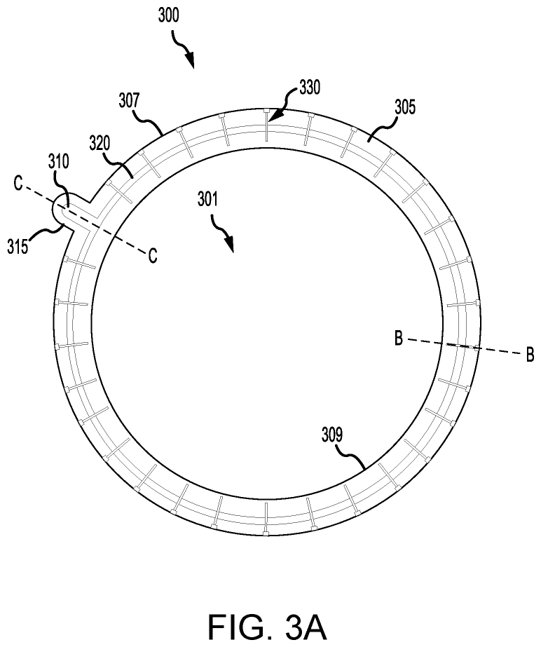

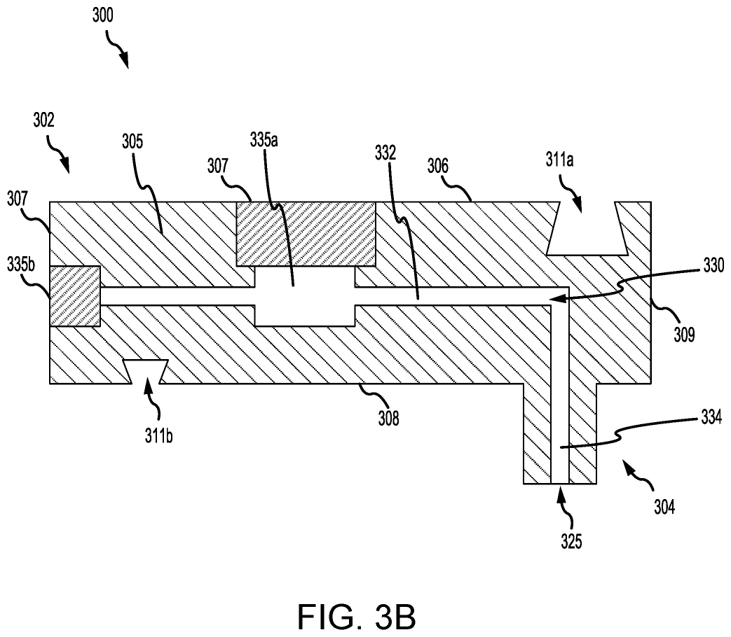

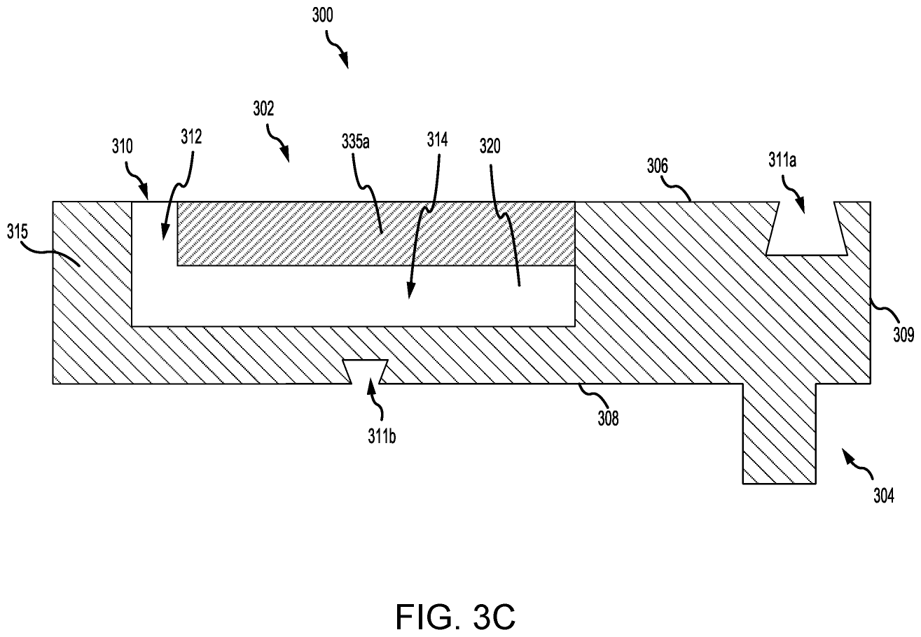

FIGS. 3A-3C show cross-sectional views of an exemplary purge ring 300 according to some embodiments of the present technology. The purge ring 300 may be included in any chamber or system previously described, as well as any other chamber or system that may benefit from the purge ring. For example, the purge ring 300 may be used as purge ring 270 and positioned between the pumping liner 260 and chamber body 202 as described in relation to FIG. 2. The purge ring 300 may be similar to the purge ring 270 and may include any of the features described in relation to purge ring 270. As best illustrated in FIG. 3A (which may be a cross-section of a purge ring, such as purge ring 270 taken along line A-A of FIG. 2), purge ring 300 may include a ring body 305, which may be formed from a processing chamber-compatible material such as, but not limited to, aluminum. The ring body 305 may be defined by an outer edge 307 and an inner edge 309, with the inner edge 309 defining an open interior 301 of the purge ring 300. An inner diameter of the ring body 305 (e.g., a diameter of the inner edge 309) may be sufficiently large that a gap is formed between the inner edge 309 and a peripheral edge of a substrate support disposed within a given processing chamber to facilitate vertical translation of the substrate support relative to the purge ring 300.

As best illustrated in FIG. 3B (which may be a cross-section taken along line B-B of FIG. 3A), the ring body 305 may be characterized by a first surface 306 and a second surface 308 that is opposite the first surface 306. When installed within a processing chamber, the first surface 306 may face a pumping liner and/or faceplate/showerhead of the processing chamber, while the second surface 308 may face and be coupled with the chamber body of the processing chamber. The ring body 305 may include an outer body 302 and an inner body 304 that defines the open interior 301. All or a portion of inner body 304 may protrude downward from the second surface 308 of the ring body 305 and may extend beyond the bottom surface of the outer body 302. For example, the inner body 304 may form and/or include a downward-extending rim such that the ring body 305 has a generally L-shaped cross-section. The inner body 304 may be sized and shaped to extend into an annular void of one or more forelines or other portion of an exhaust assembly of a processing chamber. In some embodiments, the rim portion of the inner body 304 may make up a full width of the inner body 304, while in other embodiments, an outer portion of the inner body 304 may extend beyond the bottom surface of the outer body 302, while an innermost portion of the inner body 304 may have a bottom surface that is aligned with the bottom surface of the outer body 302 and/or otherwise higher than a bottom surface of the rim.

In some embodiments, one or both of the first surface 306 and the second surface 308 may define one or more annular channels 311, which may receive one or more sealing elements such as O-rings and/or other elastomeric elements. For example, the first surface 306 may define an upper annular channel 311a and the second surface 308 may define a lower annular channel 311b. As illustrated, the upper annular channel 311a is disposed within an inner region of the ring body 305, while the lower annular channel 311b is disposed within an outer region of the ring body 305, although other configurations are possible in various embodiments. In some embodiments, the annular channels 311 may have the same size, while in other embodiments the annular channels 311 may have different sizes. For example, as illustrated the upper annular channel 311a has a cross-sectional area than the lower annular channel 311b, although other configurations are possible in various embodiments. While shown with one upper annular channel and one lower annular channel, it will be appreciated that more or fewer annular channels may be formed in the first surface 306 and/or the second surface 308.

As shown in FIGS. 3A and 3C (which may be a cross-section taken along line C-C of FIG. 3A), the purge ring 300 may define one or more gas inlets 310. For example, the ring body 305 may include a protrusion 315 that extends laterally outward from the outer surface 307. The protrusion 315 may define the gas inlet 310, which may provide a location for a fluid line for one or more gas sources (such as gas source 279) to be interfaced with the purge ring 300. In some embodiments, the protrusion 315 may sit atop and/or otherwise be exposed above or through a lid plate of a processing chamber to enable the fluid line to be readily connected to/disconnected from the gas inlet 310. An opening of the gas inlet 310 may extend through a lateral surface and/or the first surface 306 of protrusion 315 and/or other portion of the ring body 305. For example, as illustrated the gas inlet 310 may extend through the first surface 306. In some embodiments, the gas inlet 310 may include a vertical portion 312 and a horizontal portion 314. For example, the vertical portion 312 may extend through the first surface 306 and join with the horizontal portion 314, which may flow into and connect with an annular channel 320 formed within the ring body 305. As best illustrated in FIG. 3A, the annular channel 320 may extend about all or a substantial portion of the ring body 305 and the open interior 301. For example, the annular channel 320 may extend about a full circumference of the ring body 305 and the open interior 301. In other embodiments, the annular channel 320 may extend slightly less than the full circumference, such as greater than or about 300 degrees, greater than or about 310 degrees, greater than or about 320 degrees, greater than or about 330 degrees, greater than or about 340 degrees, greater then or about 350 degrees, greater than or about 355 degrees, or more. In some embodiments, rather than having a single annular channel, the purge ring may include one or more recursive channels (such as arcuate channels) that collectively extend about all or substantially all of the circumference of the ring body 305. Any number of arcuate channels may be provided, with each arcuate channel extending about at least a portion of the open interior 301. For example, the ring body 305 may define at least or about one arcuate channel, at least or about two arcuate channels, at least or about three arcuate channels, at least or about four arcuate channels, at least or about five arcuate channels, or more.

The ring body 305 may define a plurality of purge ports 325 that are disposed at different radial positions about the purge ring 300. Each of the plurality of purge ports 325 may be fluidly coupled with the annular channel 320. For example, the ring body 305 may define a number of purge channels 330 that are disposed at different radial positions about the purge ring 300. Each purge channel 330 may extend between and fluidly couple the annular channel 320 with a respective one of the purge ports 325 such that each purge port 325 shares a radial position with one of the purge channels 330. As best illustrated in FIG. 3B, each purge channel 330 may include a horizontal portion 332 and a vertical portion 334. For example, the horizontal portion 332 may extend radially inward from the annular channel 320 and terminate at a point within the inner body 304. At a point within the inner body 304, such as at a point aligned with the rim of the inner body 304, the horizontal portion 332 may join with the vertical portion 334. Vertical portion 334 may extend downward through the rim and/or other bottom surface of the inner body 304 to couple with the purge port 325 (which may extend through the bottom surface of the rim or other portion of the inner body 304). While shown with the vertical portion 334 and purge port 325 being vertical or substantially vertical (e.g., within about 15 degrees of vertical, within about 10 degrees of vertical, within about 5 degrees of vertical, within about 3 degrees of vertical, within about 1 degree of vertical, or less), it will be appreciated that other angles are possible in various embodiments. In some embodiments, the vertical portion 334 and/or purge port 325 may be angled downward and inward, while in other embodiments, the vertical portion may be omitted and the horizontal portion 332 may extend and couple directly with a purge port 325 formed within the inner surface 309. As illustrated, an outlet of each of the plurality of purge ports 325 is angled relative to a plane extending through an entirety of the annular channel 320, such as having a central axis of each purge port 325 being substantially orthogonal to the plane.

The ring body 305 may define any number of purge channels 330 and purge ports 325. For example, the ring body 305 may define at least or about 5 purge channels 330 and purge ports 325, at least or about 10 purge channels 330 and purge ports 325, at least or about 15 purge channels 330 and purge ports 325, at least or about 20 purge channels 330 and purge ports 325, at least or about 25 purge channels 330 and purge ports 325, at least or about 30 purge channels 330 and purge ports 325, at least or about 40 purge channels 330 and purge ports 325, at least or about 50 purge channels 330 and purge ports 325, at least or about 60 purge channels 330 and purge ports 325, at least or about 70 purge channels 330 and purge ports 325, at least or about 80 purge channels 330 and purge ports 325, at least or about 90 purge channels 330 and purge ports 325, at least or about 100 purge channels 330 and purge ports 325, or more, with greater numbers of purge channels 330 and purge ports 325 enabling more uniform flow of purge gas about the periphery of the open interior 301. The purge channels 330 and purge ports 325 may be provided at regular and/or irregular intervals about the ring body 305. For example, in some embodiments the purge channels 330 and purge ports 325 may be disposed at irregular intervals to account for flow non-uniformity caused by asymmetry of the processing chamber, such as due to components such as positions of forelines, slit valves, and/or other chamber components. For example, a greater density of purge ports 325 may be provided at regions further from the gas inlet 310 to promote more uniform flow conductance about the circumference of the ring body 305. In some embodiments, the purge channels 330 and purge ports 325 may extend around at least or about 270 degrees about the ring body 305, at least or about 285 degrees about the ring body 305, at least or about 300 degrees about the ring body 305, at least or about 315 degrees about the ring body 305, at least or about 330 degrees about the ring body 305, at least or about 345 degrees about the ring body 305, or more, with greater coverage enabling more uniform distribution of purge gas about the circumference of the ring body 305.

The purge ports 325 may be sized and arranged to provide substantially uniform and/or symmetrical flow conductance about a periphery of the open interior 301. In some embodiments, each of the purge ports 325 may have a same cross-sectional area, while in other embodiments some of the purge ports 325 may have different cross-sectional areas. As just one example, the cross-sectional area of each purge port 325 may vary based on a distance of the purge port 325 from the gas inlet 310. For example, purge ports 325 further from the gas inlet 310 may be larger than purge ports 325 closer to the gas inlet 310, which may help promote uniform flow conductance through each of the purge ports 325. In some embodiments, the purge ports 325 may have diameters (or other lateral dimensions and/or cross-sectional areas comparable to that of a circle of a given diameter) of less than or about 100 mils, less than or about 90 mils, less than or about 80 mils, less than or about 70 mils, less than or about 60 mils, less than or about 50 mils, less than or about 40 mils, less than or about 30 mils, less than or about 20 mils, less than or about 10 mils, or less. In some embodiments, the annular channel 320 may have a cross-sectional area that is equal to or greater than a collective cross-sectional area of each of the purge ports 325, which may ensure that sufficient gas may be flowed through the annular channel 320 to reach and flow through each of the purge ports 325 to provide substantially uniform flow conductance about the circumference of the ring body 305.

In some embodiments, the purge gas may be flowed at a rate of between or about 500 sccm and 5000 sccm at each fluid port of the purge ring, between or about 750 and 2500 sccm, or between or about 1000 sccm and 2000 sccm. The flow rate may be dependent on the type of purge gas utilized and/or other process conditions. In some embodiments, the purge gas may include O₂, CO₂, ozone, and/or other cleaning gas.

The purge ring 300 may direct purge gas into the exhaust assembly of a processing chamber during processing operations to reduce or prevent the radicals from process gases from forming residue deposits within the exhaust assembly and/or at other chamber components proximate the purge ring 300. Additionally, the purge gas may remove any residue that is present. This reduction of residue may reduce the frequency and/or intensity of cleaning operations, and may increase the service life of chamber components. Moreover, the reduction of deposits proximate a slit valve of the processing chamber may decrease contamination on wafer during the transfer process. Additionally, the flow of purge gas may also reduce throttle valve drift and improve flow conductance through the foreline. Additionally, the residue reduction of deposition within the throttle valve may reduce the frequency of high temperature purge gas cleanings of the throttle valve, which may help protect chamber components, such as the heater, from such purge gas flows.

In some embodiments, the purge ring 300 may include one or more blank offs 335. The blank offs 335 may be used to facilitate manufacture of the purge ring 300, such as by forming the channels (e.g., annular channel 320 and/or purge channels 330) through an outer surface of the ring body 305 and using the blank offs 335 to seal the machined openings. For example, a blank off 335a that covers the annular channel 320 and/or a portion of the gas inlet 310 may be interfaced and sealed against the first surface 306. This may enable the annular channel 320 and/or gas inlet 310 to be formed as a groove or open-topped channel within the first surface 306 and later sealed with blank off 335a to form a closed fluid path. Each purge channel 330 may include a blank off 335b that may seal an opening of the purge channel 330 formed through the peripheral edge (e.g., outer surface 307) of the ring body 305. This may enable the horizontal portion 332 of each purge channel 330 to be drilled or otherwise machined through the outer surface 307, with the opening within the outer surface 307 being sealed by the blank off 335b.

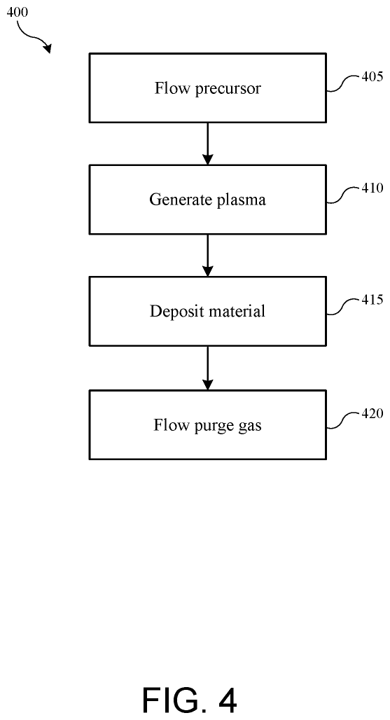

FIG. 4 shows operations of an exemplary method 400 of semiconductor processing according to some embodiments of the present technology. The method 400 may be performed in a variety of processing chambers, including processing chambers 100 and 200 described above, which may include purge rings according to embodiments of the present technology, such as purge rings 270 and 300. Method 400 may include a number of optional operations, which may or may not be specifically associated with some embodiments of methods according to the present technology.

Method 400 may include a processing method that may include operations for forming a hardmask film or other deposition operations. The method may include optional operations prior to initiation of method 400, or the method may include additional operations. For example, method 400 may include operations performed in different orders than illustrated. In some embodiments, method 400 may include flowing one or more precursors or other process gases into a processing chamber at operation 405. For example, the precursor may be flowed into a chamber, such as included in chamber 100 or 200, and may flow the precursor through one or more of a gasbox, a blocker plate, or a faceplate, prior to delivering the precursor into a processing region of the chamber.

At operation 410, a plasma may be generated of the precursors within the processing region, such as by providing RF power to the faceplate to generate a plasma. Material formed in the plasma may be deposited on the substrate at operation 415. At operation 420, the precursor may be exhausted from the processing chamber via a plenum of the pumping liner disposed atop a chamber body of the processing chamber. A purge gas may be flowed into the processing chamber via a number of purge ports formed in a purge ring that is positioned below and fluidly coupled with the pumping liner. For example, the purge gas may be flowed from a purge gas source through one or more purge gas inlets formed in the purge ring. The purge gas may then flow into an annular channel and a number of purge channels that direct the purge gas into the purge ports, with the purge ports directing the purge gas in a downward and/or downward angled direction into an exhaust assembly of the chamber. The purge gas may prevent and/or remove residue from process gases that flow into the exhaust assembly and/or other nearby chamber components. The prevention and/or removal of such residue may help extend the service life of various chamber components, including the foreline, throttle valve, and pump through which the gases may be vented. The reduction in residue within the throttle valve may help maintain proper conductance through the throttle valve and reduce the amount of throttle valve drift, which in turn may reduce the frequency of cleaning operations.

In some embodiments, the purge gas may be flowed at a rate of between or about 500 sccm and 10,000 sccm (cumulatively through all fluid ports of the purge ring), with the flow rate being dependent on what type of purge gas is used and/or other process conditions. In some embodiments, the purge gas may include O₂, CO₂, ozone, and/or other cleaning gas. In some embodiments, the purge gas may be flowed after a processing operation to clean any residue formed within a lower region of the processing chamber.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing chamber, comprising:
a chamber body having sidewalls and a base;
a pumping liner seated atop the chamber body, the pumping liner at least partially defining an annular pumping plenum and at least one exhaust aperture that fluidly couples the pumping plenum with an interior of the chamber body;
a purge ring seated below the pumping liner, wherein:
the purge ring defines an annular channel that extends about a body of the purge ring;
the purge ring defines a gas inlet that is fluidly coupled with the annular channel; and
the purge ring defines a plurality of purge ports that are disposed at different radial positions about the purge ring, each of the plurality of purge ports being aligned and in fluid communication with the pumping plenum; and
a purge gas source coupled with the gas inlet.

2. The semiconductor processing chamber of claim 1, further comprising:
an exhaust assembly fluidly coupled with the pumping plenum.

3. The semiconductor processing chamber of claim 1, wherein:
an outlet of each of the plurality of purge ports points down.

4. The semiconductor processing chamber of claim 1, further comprising:
a faceplate seated atop the purge ring.

5. The semiconductor processing chamber of claim 4, further comprising:
a thermal isolator disposed between the faceplate and the purge ring.

6. The semiconductor processing chamber of claim 1, wherein:
the purge ring comprises aluminum.

7. The semiconductor processing chamber of claim 1, wherein:
an outer surface of the purge ring comprises a lateral protrusion; and
the gas inlet is disposed on the lateral protrusion.

8. The semiconductor processing chamber of claim 7, further comprising:
a weldment that extends between and couples the purge gas source with the gas inlet.

9. A purge ring, comprising:
a ring body having a first surface and a second surface opposite the first surface, the ring body defining an open interior, wherein:
the purge ring defines an annular channel that extends about the ring body;
the purge ring defines a gas inlet that is fluidly coupled with the annular channel; and
the purge ring defines a plurality of purge ports that are disposed at different radial positions about the purge ring, the plurality of purge ports being fluidly coupled with the annular channel.

10. The purge ring of claim 9, wherein:
the plurality of purge ports provide substantially uniform flow conductance about a periphery of the open interior.

11. The purge ring of claim 9, wherein:
a cross-sectional area of the annular channel is equal to or greater than a total cross-sectional area of the plurality of purge ports.

12. The purge ring of claim 9, wherein:
the gas inlet is disposed within a lateral protrusion that extends radially outward from an outer surface of the ring body.

13. The purge ring of claim 9, wherein:
the plurality of purge ports are disposed at irregular intervals about periphery of the open interior.

14. The purge ring of claim 9, wherein:
at least some of the plurality of purge ports have different cross-sectional areas.

15. The purge ring of claim 9, wherein:
an outlet of each of the plurality of purge ports is angled relative to a plane extending through an entirety of the annular channel.

16. The purge ring of claim 15, wherein:
each of the plurality of purge ports is substantially orthogonal to the plane.

17. The purge ring of claim 9, wherein:
the purge ring defines a plurality of purge channels, wherein each purge channel of the plurality of purge channels extends between and fluidly couples the annular channel and a respective one of the plurality of purge ports.

18. A method of processing a substrate, comprising:
flowing a precursor into a processing chamber;
generating a plasma of the precursor within a processing region of the processing chamber;
depositing a material on a substrate disposed within the processing region;
exhausting the precursor from the processing chamber via a plenum of a pumping liner disposed atop a chamber body of the processing chamber; and
flowing a purge gas into the plenum of the pumping liner via a plurality of purge ports formed in a purge ring positioned below the pumping liner.

19. The method of processing a substrate of claim 18, further comprising:
venting the precursor and the purge gas from the processing chamber and the pumping liner via a foreline, a throttle valve, and a pump.

20. The method of processing a substrate of claim 18, wherein:
the purge gas comprises O₂.
